(19) United States
(12) Patent Application Publication
(10) Pub. No.: US 2012/0222731 A1
(43) Pub. Date: Sep. 6, 2012

(54) Heterojunction Solar Cell Having Amorphous Silicon Layer

(75) Inventors: Fang-Chi Hsieh, Xuzhou (CN); Li-Karn Wang, Taipei (TW)

(73) Assignees: NATIONAL TSING HUA UNIVERSITY, Hsinchu (TW); JIANGSU AIDE SOLAR ENERGY TECHNOLOGY CO.,LTD, Xuzhou (CN)

(21) Appl. No.: 13/192,439

(22) Filed: Jul. 27, 2011

(30) Foreign Application Priority Data
Mar. 2, 2011 (TW) 100107236

(51) Int. Cl. H01L 31/06

(52) U.S. Cl. 136/255

(57) ABSTRACT

The present disclosure coats an amorphous silicon (Si) layer on a doped Si substrate of a solar cell. Or, a silicon dioxide (SiO₂) layer is grown on the doped Si substrate and beneath the amorphous Si layer. A heterojunction interface and a homojunction interface are formed in the solar cell in a one-time diffusion. Thus, a heterojunction solar cell can be easily fabricated and utilities compatible to those used in modern production can still be used for reducing cost.

### TECHNICAL FIELD OF THE DISCLOSURE

The present disclosure is related to a solar cell, and more particularly, is related to coating an amorphous silicon (Si) layer on a Si substrate for fabricating a heterojunction solar cell with ease.

### DESCRIPTION OF THE RELATED ARTS

A Si solar cell having a P-N junction will generate free carriers, i.e. electrons and holes, after absorbing light. Then, the carriers are driven by a built-in electric field at the P-N junction to be gathered at the negative and positive poles for generating power to an external circuit. At present, commercially such a solar cell is fabricated by using a p-doped Si wafer at first. An alkali solution is used for obtaining a textured surface on each side of the wafer. Then, phosphorous diffusion is processed to form a P-N junction at the front side. Then, through the processes of antireflection coating, contact printing, sintering and etc, a solar cell having the P-N junction is completed. An amorphous Si layer is introduced to reduce the surface recombination velocity of carriers for improving open circuit voltage and short circuit current and henceforth the optoelectric conversion efficiency of the solar cell.

An example is a Si solar cell having a heterojunction with intrinsic thin layer (HIT) by Sanyo Electric Co., Ltd., whose conversion efficiency reaches 23 percent (%) (E. Maruyama, et al., “Sanyo's challenges to the development of high-efficiency HIT solar cells and the expansion of HIT business”, Conference Record of the 4th World Conference on Photovoltaic Energy Conversion (WCPEC-4), Hawaii, May 2006; and, Photovoltaic Device, US patent, US 2006/0065297A1, 2006). The HIT solar cell is fabricated by separately growing intrinsic amorphous Si layers on front and back surfaces of an n-type Si substrate at a lower temperature, like 200 degrees Celsius (° C.), at first. Then a p-type amorphous Si layer is grown on the front surface and an n-type amorphous Si layer on the back surface. Thus, a PIN structure with a heterojunction is formed at the front side of the solar cell; and a back surface field with a heterojunction at the back side. All these amorphous Si layers are grown through a plasma chemical vapor deposition method. Because conductivity of an amorphous Si layer are worse than that of a crystalline Si layer, transparent conductive oxide layers are separately coated on the front and back surfaces of the HIT solar cell through sputtering. The transparent conductive oxide layers are used to improve the carrier transmission rates on the one hand, and to achieve antireflection at the front surface on the other hand.

To achieve a high efficiency for the HIT solar cell, some techniques are introduced, including surface washing of the Si substrate; passivation on the surfaces of the Si substrate by using intrinsic amorphous Si layers; high open circuit voltage formed by a heterojunction between the amorphous Si layer and the crystalline Si substrate; and low-temperature fabrication. Therein, the low-temperature fabrication is done to prevent amorphous Si layers from converting into crystalline Si layers for retaining characteristics of wide energy gap and heterojunction. Because of an abrupt covalence band offsets between a p-type amorphous Si layer and a n-type crystalline Si substrate with a high potential difference formed at the interface, the number of majority carriers around the interface is decreased, henceforth reducing the recombination velocity of the carriers and enhancing the performance of the solar cell. However, if the p-type amorphous Si layer is directly contacted with the Si substrate, defects would occur around the interface and performance of the solar cell would be reduced. Hence, an intrinsic amorphous Si layer is grown between the p-type amorphous Si layer and the n-type Si substrate to obtain passivation at the interface and keep the heterojunction structure for enhancing the solar cell. The intrinsic amorphous Si layer uses hydrogen atoms contained within to amend defects of the interface between the crystalline Si substrate and the amorphous Si layer. Yet, at a high temperature, like more than 300° C., the hydrogen atoms are diffused and move to the p-type amorphous Si layer and disabled the passivation. For stopping the diffusion of the hydrogen atoms, concentrations of the hydrogen atoms and boron atoms at the interface between the p-type amorphous Si layer and the intrinsic amorphous Si layer are adjusted. Therein, a diffusion reducing area is formed at the interface to reduce diffusion of the hydrogen atoms (Photovoltaic Device, US patent, US 2006/0065297AI, 2006).

To prevent loosing function of the heterojunction interface (e.g. passivation of the interface between a crystalline Si substrate and an amorphous Si layer) by restraining the crystallization of the amorphous Si layer and retaining a layer having a wide energy band gap, Applied Materials, Inc. announced a technique wherein a silicon dioxide (SiO₂) layer of about one nanometer (nm) in thickness is grown between a crystalline Si substrate and an amorphous Si layer. Then, an intrinsic amorphous Si layer and a doped amorphous Si layer are sequentially deposited to form an HIT solar cell (HIT Solar Cell Structure, US patent, US 2010/0186802A1, 2010).

An alternative to HIT is to form a P-N junction at the front surface of a Si substrate through diffusion at first. Then, an intrinsic amorphous Si layer and a doped amorphous Si layer are sequentially grown both on the front surface and the back surface of the Si substrate. At last, a transparent conductive oxide layer is coated on the front and the back surfaces. The front and the back surfaces are then printed with the electrodes to thus obtain a Si solar cell having a homojunction and a heterojunction at the same time (Solar Cell Having Crystalline Silicon P-N Homojunction and Amorphous Silicon Heterojunction for Surface Passivation, US patent, US 2009/0211627A1, 2009). This prior art grows a SiO₂ layer on both surfaces of the Si substrate in a thermal oxygen environment and removes the SiO₂ layers subsequently through wet etching for removing contaminating impurity in the Si material. As shown in FIG. 3, a Si-substrate solar cell 300 having a homojunction interface and a heterojunction interface has a Si substrate 310; and a diffusion layer 320 formed on the Si substrate 310. The diffusion layer 320 is obtained through diffusion to form a P-N homojunction interface having an opposite electrical doping to the Si substrate 310 on a surface area of the Si substrate 310. Then, intrinsic amorphous Si layers 330,335 and doped amorphous Si layers 340,345 are deposited on the front and the back surfaces of the Si substrate 310, respectively. Therein, heterojunctions are formed between the diffusion layer 320 and the intrinsic amorphous Si layer 330 and between the Si substrate 310 and the intrinsic amorphous Si layer 335; the intrinsic amorphous Si layers 330,335 are used for passivation at interfaces; and, the doped amorphous Si layers 340,345 provide enhanced built-in electric fields for attracting carriers. Thus, this prior art obtains a wide energy band gap, reduces surface recombination velocity of the carriers at the interfaces and improves the open circuit voltage and the short circuit current. In a word, the conversion rate of the solar cell is increased. This prior art also includes processes of forming transparent conductive oxide layers 350,355; and coating the front electrode 360 and the back electrode 365 through screen printing.

However, the above prior arts all require multiple amorphous Si layers with high cost, long fabrication time and complicated procedure, which are not fit for mass production. Hence, the prior arts do not fulfill all users' requests on actual use.

### SUMMARY OF THE DISCLOSURE

The main purpose of the present disclosure is to deposit an intrinsic amorphous silicon (Si) layer on a crystalline Si substrate for fabricating a heterojunction solar cell with ease.

The second purpose of the present disclosure is to depositing an intrinsic amorphous Si layer, or growing a silicon dioxide (SiO₂) layer onto a doped Si substrate, to obtain a heterojunction interface, and to obtain a homojunction interface in a solar cell at the same time for economic fabrication with utilities compatible to those used in modern production.

To achieve the above purposes, the present disclosure is a heterojunction solar cell having an intrinsic amorphous Si layer, comprising a crystalline Si substrate, an intrinsic amorphous Si layer, a transparent conductive oxide layer, a front electrode and a back electrode, where the Si substrate is electrically doped with an original concentration smaller than 10¹⁹ cm⁻³ and has a Si-substrate surface area and a back-surface field area on a front surface and a back surface, respectively; the front surface of the Si substrate has a homojunction interface; the intrinsic amorphous Si layer is deposited on the Si-substrate surface area; the intrinsic amorphous Si layer has an electronic energy band gap bigger than the Si substrate; a diffusion area is formed both at the intrinsic amorphous Si layer and the Si-substrate surface area; the transparent conductive oxide layer is coated on the intrinsic amorphous Si layer; the front electrode has a grid line form coated on the transparent conductive oxide layer; the back electrode is coated on the back surface of the Si substrate producing a back-surface field area after firing; and the heterojunction between the intrinsic amorphous Si layer and the Si substrate and the homojunction on the front surface of the Si substrate are formed through electrical doping in a one-time diffusion. Accordingly, a novel heterojunction solar cell having an intrinsic amorphous Si layer is obtained.

### BRIEF DESCRIPTIONS OF THE DRAWINGS

The present disclosure will be better understood from the following detailed descriptions of the preferred embodiments according to the present disclosure, taken in conjunction with the accompanying drawings, in which

FIG. 1 is the view showing the first preferred embodiment according to the present disclosure;

FIG. 2 is the view showing the second preferred embodiment; and

FIG. 3 is the view of the prior art.

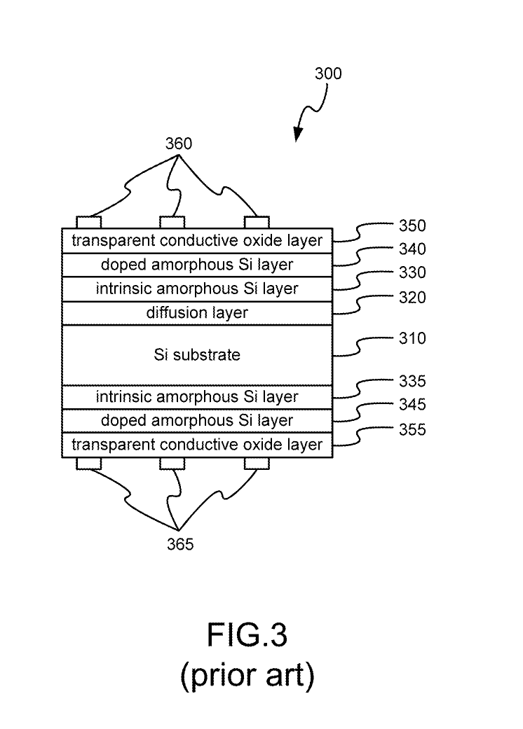

### DESCRIPTION OF THE PREFERRED EMBODIMENTS

The following description of the preferred embodiments is provided to understand the features and the structures of the present disclosure.

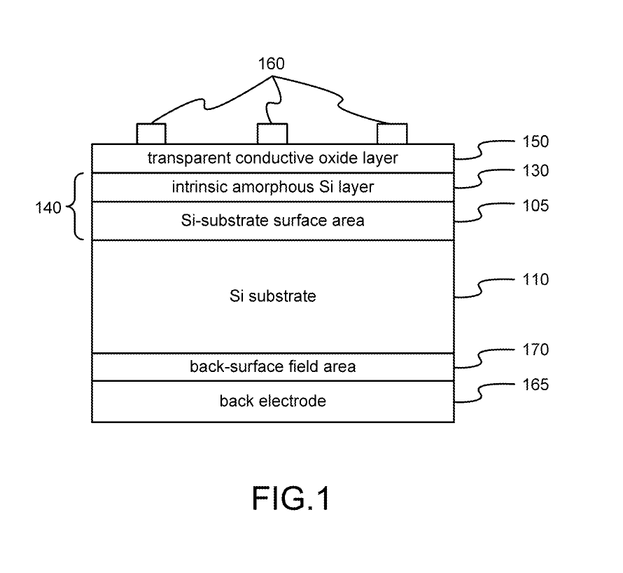

Please refer to FIG. 1, which is a view showing a first preferred embodiment according to the present disclosure. As shown in the figure, the present disclosure is a heterojunction solar cell having intrinsic amorphous silicon (Si) layer, comprising a Si substrate 110, an intrinsic amorphous Si layer 130, a transparent conductive oxide layer 150, a front electrode 160 and a back electrode 165. Therein, the Si substrate 110 is electrically doped; the Si substrate 110 has a Si-substrate surface area 105 and a back-surface field area 170 on a front surface and a back surface, respectively; the front surface of the Si substrate 110 has a homojunction interface; the intrinsic amorphous Si layer 130 is coated on the Si-substrate surface area 105 on the front surface of the Si substrate 110; the intrinsic amorphous Si layer 130 has an electronic energy band gap bigger than the Si substrate 110; a diffusion area 140 is formed both at the intrinsic amorphous Si layer 130 and the Si-substrate surface area 105; the transparent conductive oxide layer 150 is coated on the intrinsic amorphous Si layer 130; the front electrode 160 has a grid line form coated on the transparent conductive oxide layer 150; the intrinsic amorphous Si layer 130 is heterojunctioned to the Si substrate 110; the back electrode 165 is coated on the back surface of the Si substrate 110 producing the back-surface field area 170 after firing; the Si substrate 110 has an original doping concentration smaller than 10¹⁹ cm⁻³; the front surface of the Si substrate 110 is a textured surface; the Si substrate 110 has a thickness of 50˜660 micrometers (μm); the intrinsic amorphous Si layer 130 has a thickness of 1˜70 nanometers (nm); the transparent conductive oxide layer 150 has a thickness smaller than 350 nm; the transparent conductive oxide layer 150 is made of ITO (indium tin oxide), SnO₂ (tin dioxide), AZO (aluminum zinc oxide) or ZnO (zinc oxide); the front and back electrodes 160,165 are made of silver paste, aluminum paste, or a mixture of aluminum paste and silver paste; and the heterojunction between the intrinsic amorphous Si layer 130 and the Si substrate 110 and the homojunction interface on the front surface of the Si substrate 110 are formed through electrical doping in a one-time diffusion.

On fabricating the present disclosure, a doped Si substrate 110 is processed to obtain an intrinsic amorphous Si layer 130 grown upon through plasma-enhanced chemical vapor deposition (PECVD). The PECVD is processed at a low temperature to obtain a wide energy band gap for the intrinsic amorphous Si layer 130. However, the intrinsic amorphous Si layer 130 will experience a higher temperature during diffusion at a later stage to form crystallized micro-crystal silicon. Hence, the deposition of the intrinsic amorphous Si layer 130 can be a low-pressure chemical vapor deposition (LPCVD) processed at a higher temperature below 700 degrees Celsius (° C.)

Then, the diffusion for electrical doping is processed, wherein a dopant is selected to obtain a doping of a diffusion area 140 that is electrically opposite to that of the Si substrate 110, with the diffusion area 140 comprising the intrinsic amorphous Si layer 130 and the Si-substrate surface area 105. That is, for example, if the Si substrate is made of p-doped silicon, the diffusion area is made of n-doped silicon and the doping concentration of the intrinsic amorphous Si layer 130 is higher than that of the Si-substrate surface area 105. Then, a transparent conductive oxide layer 150 is coated on the intrinsic amorphous Si layer 130; a front electrode 160 having a grid line form is coated on the transparent conductive oxide layer 150; and, a back electrode 165 is coated on a back surface of the Si substrate 110. After the front and the back electrodes 160,165 are coated, a co-firing process is undertaken for forming a good electrical contact between the front electrode 160 and the transparent conductive oxide layer 150 and for forming a back-surface field area 170 on a back surface of the Si substrate 110. Because the conductivity of the transparent conductive oxide layer 150 may be reduced after co-firing the front and the back electrodes 160,165, another choice for the present disclosure is that, after the diffusion for electrical doping, the back electrode 165 is coated at first followed by a sintering between 650° C. and 850° C. for forming the back-surface field area 170 on the back surface of the Si substrate 110; and, then, the transparent conductive oxide layer 150 is coated followed by the coating of the front electrode 160 as well as the sintering of the front electrode 160. At this moment, the temperature for sintering the front electrode 160 can be between 300° C. and 700° C. only, which would not affect the conductivity of the transparent conductive oxide layer 150 and the front electrode 160 would obtain good electrical contact with it.

The Si substrate 110 can further have an aluminum oxide layer (not shown in the figure) beneath the intrinsic amorphous silicon layer 130, wherein the aluminum oxide layer has a thickness not bigger than 10 nm.

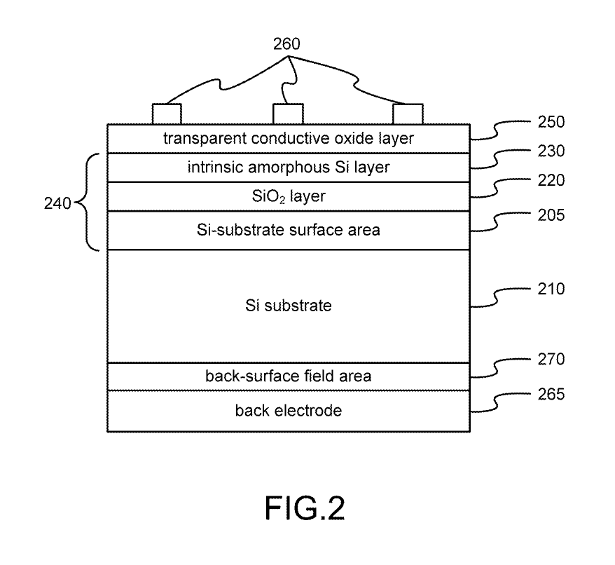

Please refer to FIG. 2, which is a view showing a second preferred embodiment. As shown in the figure, the present disclosure is a heterojunction solar cell having intrinsic amorphous Si layer, comprising a Si substrate 210, a silicon dioxide (SiO₂) layer 220, an intrinsic amorphous Si layer 230, a transparent conductive oxide layer 250, a front electrode 260 and a back electrode 265. Therein, the Si substrate 210 is electrically doped to obtain an original doping concentration smaller than 10¹⁹ cm⁻³; the Si substrate 210 has a Si-substrate surface area 205 and a back-surface field area 270 on a front surface and a back surface, respectively; the front surface of the Si substrate 210 has a homojunction interface; the SiO₂ layer 220 is grown on the Si-substrate surface area 205 on the front surface of the Si substrate 210; the intrinsic amorphous Si layer 230 is coated on the SiO₂ layer 220; the intrinsic amorphous Si layer 230 has an electronic energy band gap bigger than that of the Si substrate 210; the intrinsic amorphous Si layer 230 has a heterojunction interface between the intrinsic amorphous Si layer 230 and the Si substrate 210; a diffusion area 240 is formed at the intrinsic amorphous Si layer 230, the Si-substrate surface area 205 and the SiO₂ layer 220; the transparent conductive oxide layer 250 is coated on the intrinsic amorphous Si layer 230; the front electrode 260 has a grid line form coated on the transparent conductive oxide layer 250; the back electrode 265 is coated on the back surface of the Si substrate 210 producing the back-surface field area 270 after firing; the SiO₂ layer 220 has a thickness not bigger than 10 nm.

The present disclosure has the SiO₂ layer 220 on the Si substrate 210. The SiO₂ layer 220 is formed through a chemical growth process. That is, the Si substrate 210 is immersed in the chemical solution to form the SiO₂ layer 220 with a thickness depending on how long the Si substrate 210 is immersed. In the chemical growth process, the chemical solution comprises at least a nitric acid solution, a sulfuric acid solution, a hydrochloric acid solution, a hydrogen peroxide solution, an ammonia solution or a phosphorous acid solution; and the chemical solution has a weight concentration not smaller than 5%. Furthermore, the Si substrate 210 is immersed for at least 2 minutes (min) at a temperature not lower than 4° C. After forming the SiO₂ layer 220 through immersion, the Si substrate 210 is annealed for at least 3 min at a temperature between 100° C.˜1100° C. The purpose for growing the SiO₂ layer 220 is, on one hand, to amend dangling bonds at the surface of the Si substrate 210; and, on the other hand, to restrain crystallization of the intrinsic amorphous Si layer 230 that would otherwise occurs in the high-temperature environment. During immersion, a SiO₂ layer will be formed on the back surface of the Si substrate 210, too. Because the SiO₂ layer is not thick, carriers can penetrate easily. After the growing of the SiO₂ layer 220, PECVD or LPCVD is processed to grow the intrinsic amorphous Si layer 230 and, then, electrical doping is processed through diffusion subsequently, resulting in the diffusion area 240 that thus comprises the intrinsic amorphous Si layer 230, the SiO₂ layer 220 and the Si-substrate surface area 205. Therein, the intrinsic amorphous Si layer 230 has a doping concentration higher than the Si-substrate surface area 205. Then, the transparent conductive oxide layer 250, the front electrode 260 and the back electrode 265 are coated; and, after sintering, the back-surface field area 270 is formed on the back surface of the Si substrate 210.

The dopant used for doping the intrinsic amorphous Si layer 130,230 can be the same as that for the Si-substrate surface area 105,205, but different from that for the Si substrate 110,210. Or, the dopant used for doping the intrinsic amorphous Si layer 130,230 can be the same as that for the Si-substrate surface area 105,205 and can be also the same as that for the Si substrate 110,210 while the intrinsic amorphous Si layer 130,230 has a doping concentration higher than the Si substrate 110,210.

The transparent conductive oxide layers in the two preferred embodiments described above can be replaced by transparent dielectric layers, such as SiNx (silicon nitride) and SiO₂ (silicon dioxide) layers, to form another set of preferred embodiments for the present disclosure.

To sum up, the present disclosure is a heterojunction solar cell having an intrinsic amorphous Si layer, where multiple layers of amorphous Si are not required and only one intrinsic amorphous Si layer grown on a surface of a Si substrate, or a SiO₂ layer formed through a chemical growth, is required for a heterojunction solar cell; the Si substrate covered with the intrinsic amorphous Si layer is doped through diffusion to obtain a heterojunction interface and a homojunction interface for the solar cell at one time and at the same time; and, thus, the present disclosure can be fabricated economically and easily for mass production.

The preferred embodiments herein disclosed are not intended to unnecessarily limit the scope of the disclosure. Therefore, simple modifications or variations belonging to the equivalent of the scope of the claims and the instructions disclosed herein for a patent are all within the scope of the present disclosure.

What is claimed is:

1. A heterojunction solar cell having amorphous silicon (Si) layer, at least comprising:
a Si substrate, said Si substrate being electrically doped, said Si substrate having a Si-substrate surface area on a front surface of said Si substrate, said Si substrate having a back-surface field area on a back surface of said Si substrate, said front surface of said Si substrate having a homojunction interface, said Si substrate having an original doping concentration smaller than 1019 cm⁻³;
an amorphous Si layer, said amorphous Si layer being coated on said Si-substrate surface area on said front surface of said Si substrate, said amorphous Si layer having an electronic energy band gap bigger than said Si substrate, said amorphous Si layer producing a heterojunction between said amorphous Si layer and said Si substrate, said heterojunction being obtained through electrical doping;
a transparent dielectric layer, said transparent dielectric layer being coated on said amorphous Si layer on said front surface of said Si substrate;
a front electrode, said front electrode having a grid line form, said front electrode being coated on said transparent dielectric layer; and
a back electrode, said back electrode being coated on said back-surface field area on said back surface of said Si substrate,
wherein a diffusion area includes said amorphous Si layer and said Si-substrate surface area; and
wherein said heterojunction between said amorphous Si layer and said Si substrate and said homojunction interface on said front surface of said Si substrate are obtained through electrical doping in a one-time diffusion.

2. The solar cell according to claim 1,
wherein said Si substrate has a thickness of 50˜660 micrometers (μm).

3. The solar cell according to claim 1,
wherein said front surface of said Si substrate is a textured surface.

4. The solar cell according to claim 1,
wherein said transparent dielectric layer is made of a material selected from a group consisting of SiNx, SiO2, ITO, SnO2, AZO and ZnO.

5. The solar cell according to claim 1,
wherein said amorphous Si layer is doped with the same dopant as said Si-substrate surface area and is not doped with the same dopant as said Si substrate.

6. The solar cell according to claim 1,
wherein said amorphous Si layer is doped with the same dopant as said Si-substrate surface area and is doped with the same dopant as said Si substrate as well and said amorphous Si layer has a doping concentration higher than said Si substrate.

7. The solar cell according to claim 1,
wherein said Si substrate further has an aluminum oxide layer beneath said amorphous Si layer at said front surface of said Si substrate; and
wherein said aluminum oxide layer has a thickness not bigger than 10 nanometers (nm).

8. The solar cell according to claim 1,
wherein said transparent dielectric layer is obtained through coating after sintering said back electrode.

9. A heterojunction solar cell having amorphous Si layer, at least comprising:
a Si substrate, said Si substrate being electrically doped, said Si substrate having a Si-substrate surface area on a front surface of said Si substrate, said Si substrate having a back-surface field area on a back surface of said Si substrate, said front surface of said Si substrate having a homojunction interface, said Si substrate having an original doping concentration smaller than 10¹⁹ cm⁻³;
a silicon dioxide (SiO₂) layer, said SiO₂ layer being coated on said Si-substrate surface area on said front surface of said Si substrate;
an amorphous Si layer, said amorphous Si layer being coated on said SiO2 layer on said front surface of said Si substrate, said amorphous Si layer having an electronic energy band gap bigger than said Si substrate, said amorphous Si layer producing a heterojunction between said amorphous Si layer and said Si substrate, said heterojunction being obtained through electrical doping;
a transparent dielectric layer, said transparent dielectric layer being coated on said amorphous Si layer on said front surface of said Si substrate;
a front electrode, said front electrode having a grid line form, said front electrode being coated on said transparent dielectric layer; and
a back electrode, said back electrode being coated on said back-surface field area on said back surface of said Si substrate,
wherein a diffusion area includes said amorphous Si layer, said Si-substrate surface area and said SiO₂ layer; and
wherein said heterojunction between said amorphous Si layer and said Si substrate and said homojunction interface on said front surface of said Si substrate are obtained through electrical doping in a one-time diffusion.

10. The solar cell according to claim 9,
wherein said Si substrate has a thickness of 50 μm˜660 μm.

11. The solar cell according to claim 9,
wherein said front surface of said Si substrate is a textured surface.

12. The solar cell according to claim 9,
wherein said transparent dielectric layer is made of a material selected from a group consisting of SiNx, SiO2, ITO, SnO2, AZO and ZnO.

13. The solar cell according to claim 9,
wherein said amorphous Si layer is doped with the same dopant as said Si-substrate surface area and is not doped with the same dopant as said Si substrate.

14. The solar cell according to claim 9,
wherein said amorphous Si layer is doped with the same dopant as said Si-substrate surface area and is doped with the same dopant as said Si substrate as well while said amorphous Si layer has a doping concentration higher than said Si substrate.

15. The solar cell according to claim 9,
wherein said SiO2 layer has a thickness not bigger than 10 nm.

16. The solar cell according to claim 9,
wherein said SiO2 layer is obtained through immersing said Si substrate in a chemical solution.

17. The solar cell according to claim 16,
wherein said chemical solution comprises at least a solution selected from a group consisting of a nitric acid solution, a sulfuric acid solution, a hydrochloric acid solution, a hydrogen peroxide solution, an ammonia solution and a phosphorous acid solution;
wherein said chemical solution has a weight concentration not smaller than 5%; and
wherein said Si substrate is immersed in said chemical solution for at least 2 minutes (min) at a temperature not lower than 4° C.

18. The solar cell according to claim 16,
wherein, after obtaining said SiO2 layer by immersing said Si substrate, said SiO2 layer is annealed at a temperature higher than 100 degrees Celsius (° C.) for at least 3 min.

19. The solar cell according to claim 9,
wherein said SiO2 layer is obtained at a temperature between 700° C.˜1300° C. in an oxygen environment.

20. The solar cell according to claim 9,
wherein said transparent dielectric layer is obtained through coating after sintering said back electrode.
